(19) United States
(12) Patent Application Publication
(10) Pub. No.: US 2013/0125962 A1
(43) Pub. Date: May 23, 2013

(54) METHOD FOR MANUFACTURING LIGHT ABSORBER LAYER OF BISMUTH-DOPED IB-IIIA-VIA COMPOUND AND SOLAR CELL INCLUDING THE SAME

(71) Applicant: NATIONAL TAIWAN UNIVERSITY, Taipei (TW)

(72) Inventors: Chung-Hsin LU, Taipei (TW); Fu-Shan CHEN, Tainan City (TW)

(73) Assignee: NATIONAL TAIWAN UNIVERSITY, TAIPEI (TW)

(21) Appl. No.: 13/684,128

(22) Filed: Nov. 21, 2012

(30) Foreign Application Priority Data
Nov. 22, 2011 (TW) 100142833
Nov. 20, 2012 (TW) 101143298

(51) Int. Cl. H01L 31/032; H01L 31/18

(52) U.S. Cl. CPC H01L 31/0321; H01L 31/18
USPC 136/252; 438/93

(57) ABSTRACT

A technique for enhancing the characterization of the light absorber layers and the solar cells employing the light absorber layers are provided. A method for preparing the light absorber layers includes that bismuth-doped IB-IIIA-VIA compounds are synthesized via heating Group IB, Group IIIA and bismuth compound in an atmosphere containing Group VIA species. Additionally, a technique for preparing a solar cell employing IB-IIIA-VIA compounds containing bismuth species, that are prepared via the aforementioned method and further applied to manufacture photovoltaic to materials, is also provided.

### RELATED APPLICATIONS

This application claims priority to Taiwan Application Serial Numbers 100142833, filed Nov. 22, 2011 and 101143298, filed Nov. 20, 2012, which are herein incorporated by references.

### BACKGROUND

1. Field of Invention

The invention relates to a method for manufacturing IB-IIIA-VIA compounds. More particularly, the invention relates to a method for manufacturing bismuth-doped IB-IIIA-VIA compounds used as photovoltaic material devices.

2. Description of Related Art

In recent years, due to the influence of global climatic variation, environmental pollution and the growing shortage of resources, the solar photovoltaic industry is excited to flourish under the improvement of environmental awareness and the warning of energy crisis. In various solar cells, a copper indium gallium selenide (Cu(In,Ga)Se₂, CIGS) solar cell has been given great attention due to its advantages such as high conversion efficiency, good stability, low material cost, and capable of forming a thin film.

The CIGS compound has a chalcopyrite structure, which mainly consists of Group IB-IIIA-VIA compounds. The CIGS compound is a direct bandgap semiconductor material, which can change the band gap of semiconductors by regulating the composition and is a main material currently often used in light absorber layers of the solar cells. In the existing technique for manufacturing the light absorber layers of the CIGS solar cells, different ions are often doped to increase the quality of the light absorber layers, so as to enhance the photovoltaic conversion efficiency of the cells. A method for adding antimony (Sb) to enhance the photovoltaic characteristics is disclosed in US20090320916. However, the doping amounts of antimony in the above light absorber layers are limited, and the concentration of antimony in the light absorber layers is difficult to control, which indirectly affects the characteristics of the light absorber layers. In this view, if a new doping element is found and the doping concentration of the new doping element can be effectively controlled, the new doping element would contribute to improve the grain size and the grain growth of the light absorber layers, so as to increase the photovoltaic conversion efficiency of the devices.

### SUMMARY

For achieving the above and other aspects, the invention provides a method for manufacturing light absorber layers of bismuth-doped IB-IIIA-VIA compounds, which is characterized in that the method includes: (A) depositing a precursor thin film containing Group IB, Group IIIA and bismuth compounds, and (B) then heating the precursor thin film in an atmosphere containing Group VIA species, to further form light absorber layers of the bismuth-doped IB-IIIA-VIA compounds.

According to an embodiment of the invention, the Group IB element is selected from a group consisting of copper, silver, gold and a combination thereof; the Group IIIA element is selected from a group consisting of boron, aluminum, gallium, indium, thallium and a combination thereof; the Group VIA element is selected from a group consisting of oxygen, sulfur, selenium, tellurium, polonium and a combination thereof; and the mole ratio of the IB-IIIA-VIA to the bismuth is from 10:1 to 2000:1.

According to an embodiment of the invention, the above step (A) further includes adding Group IA and/or Group VIA compounds into the precursor thin film; the depositing method of the above step (A) includes a vacuum film-coating process, an non-vacuum film-coating process or a combination thereof; the depositing method of the above step (A) includes coating, sputtering, evaporation or a combination thereof; the coating method of the above step (A) includes spin coating, slot coating, extrusion coating, curtain coating, slide coating, dipping, doctor blade coating or a combination thereof; the atmosphere of the above step (B) includes vacuum or non-vacuum; and the atmosphere includes oxygen (O₂), nitrogen (N₂), hydrogen (H₂), argon (Ar), hydrogen selenide (H₂Se), hydrogen sulfide (H₂S), selenium (Se) steam, sulfur (S) steam, tellurium (Te) steam or a combination thereof.

According to an embodiment of the invention, the above step (A) further includes a heat treatment process for the precursor film. The heat treatment temperature ranges from 50° C. to 650° C., and the heat treatment time ranges from 15 min to 12 hr. The heat treatment process can improve the film quality and surface morphology, dry the film, remove the residual carbon, or increase the density. The heat treatment process atmosphere includes oxygen (O₂), nitrogen (N₂), argon (Ar) or a combination thereof.

The invention also provides a solar cell employing light absorber layers of bismuth-doped IB-IIIA-VIA compounds. The solar cell is manufactured by the above method for manufacturing the light absorber layers of the bismuth-doped IB-IIIA-VIA compounds.

The light absorber layers of the bismuth-doped IB-IIIA-VIA compounds synthesized according to the invention can be applied as photovoltaic material devices. The light absorber layers of the bismuth-doped IB-IIIA-VIA compounds can not only contribute to the grain size and the grain growth of the IB-IIIA-VIA compounds, but also improve the electrical characteristics of the IB-IIIA-VIA compounds, so that advantages of the characteristics of the photovoltaic devices can be increased.

According to an embodiment of the invention, the average grain size of the bismuth-doped IB-IIIA-VIA compounds of the light absorber layers is greater than or equal to 0.6 μm, preferably greater than or equal to 0.8 μm, and most preferably greater than or equal to 1.0 μm.

In order to make the foregoing as well as other aspects, features and advantages of the invention more apparent various embodiments are taken as examples hereinafter to make a detailed description with reference to the accompanying drawings.

### BRIEF DESCRIPTION OF THE DRAWINGS

FIG. 1 is a schematic diagram of a solar cell according to an embodiment of the invention;

FIG. 2 is an X-ray diffraction pattern of a thin film sample 1 of the Embodiment 1;

FIG. 3 is a scanning electron microscope (SEM) diagram of the thin film sample 1 of the Embodiment 1;

FIG. 4 is a current density-voltage diagram of a copper indium gallium selenide thin film solar cell 1 of the Embodiment 1;

FIG. 5 is a scanning electron microscope (SEM) diagram of a thin film sample 2 of the Comparative Embodiment 1; and

FIG. 6 is a current density-voltage diagram of a copper indium gallium selenide thin film solar cell 2 of the Comparative Embodiment 1.

### DETAILED DESCRIPTION

The Detailed Description is described by specific examples hereinafter. However, these embodiments are only examples of the invention, and are not intended to limit the scope of the invention. Those of skills in the art can make appropriate variations as required according to the disclosure of the specification and the claims hereinafter, while these variations are all included in the scope of the invention.

The invention provides a method for manufacturing bismuth-doped IB-IIIA-VIA compounds, wherein the bismuth-doped IB-IIIA-VIA compounds are synthesized via heating the Group IB, Group IIIA and bismuth compounds in the atmosphere containing the Group VIA species. Furthermore, in the method of the invention, firstly raw materials containing the Group IB, Group IIIA and bismuth compounds or a combination thereof are mixed uniformly and deposited on a substrate by means of coating, sputtering or evaporation to form precursor compounds, and then the precursor compounds are heated in the atmosphere containing the Group VIA species.

The raw materials containing the Group IB, Group IIIA and bismuth or a combination thereof used in the method of the invention refer to alloy and/or compounds containing the Group IB and/or the Group IIIA and/or the bismuth and/or a combination thereof, including alloy, oxide, nitrate, acetate, sulfate, oxalate or carbonate. Examples of the raw materials containing the Group IB element include alloy, fluoride, chloride, bromide, iodide, nitrate, acetate, sulfate, oxalate or carbonate of copper, silver, gold or a combination thereof; and the alloy or nitrate of copper, silver, gold or a combination thereof is preferred, such as copper (Cu), silver (Ag), gold (Au), copper nitrate (Cu(NO₃)₂), copper nitrite (CuNO₃), silver nitrate (Ag(NO₃)₂), gold nitrate (Au(NO₃)₂). Examples of the rave material containing the Group IIIA element include alloy, fluoride, chloride, bromide, iodide, nitrate, acetate, sulfate, oxalate or carbonate of boron, aluminum, gallium, indium, thallium or a combination thereof; and the alloy or nitrate of boron, aluminum, gallium, indium, thallium or a combination thereof is preferred, such as aluminum (Al), gallium (Ga), indium (In), aluminum nitrate (Al(NO₃)₃), gallium nitrate (Ga(NO₃)₃), indium nitrate (In(NO₃)₃). Examples of the raw materials containing the bismuth element include alloy, fluoride, chloride, bromide, iodide, nitrate, acetate, sulfate, oxalate or carbonate; and the metal form or nitrate of bismuth is preferred, such as bismuth (Si), bismuth nitrate (Bi(NO₃)₃). Examples of the raw materials containing the Group VIA element include oxide, halide, oxyhalide, sulfide, selenide, amide, urea compound, selenate, sulfate or tellurate of sulfur (S), selenium (Se), tellurium (Te) or a combination thereof, such as selenium oxide (SeO₂), tellurium oxide (TeO₂), sulfuric acid (H₂SO₄), selenic acid (H₂SeO₄), telluric acid (H₂TeO₄), sulfinic acid (H₂SO₃), seleninic acid (H₂SeO₃), tellurous acid (H₂TeO₃), thiourea (CS(NH₂)₂), selenourea (CSe(NH₂)₂), selenium dichloride (SeCl₂), selenium tetrachloride (SeCl₄), tellurium dichloride (TeCl₂), tellurium tetrachloride (TeCl₄), selenium dibromide (SeBr₂), selenium tetrabromide (SeBr₄), tellurium dibromide (TeBr₂), tellurium tetrabromide (TeBr₄), selenium oxydichloride (SeOCl₂) or selenium sulfide (SeS₂). However, a selection of the above compounds is not limited to the above-mentioned compounds, and all of the compounds containing the Group IB, the Group IIIA, the bismuth element and the Group VIA are possible.

The mole ratio of the Group IB-IIIA-VIA compounds to the bismuth is about (10-2000):1, preferably about (20-1000):1, and most preferably about (40-500):1.

In the method of the invention, the above-mentioned raw material containing the Group IB, Group IIIA and bismuth compounds is deposited on the substrate firstly, wherein a deposited thickness is about 0.1-20 μm, preferably 0.2-15 μm, and most preferably 0.5-10 μm. Depositing method to be selected includes a vacuum process technique, a non-vacuum process technique or a combination thereof, such as co-evaporation, sputtering, coating process, chemical spray pyrolysis or electrodeposition. The coating process includes spin coating, slot coating, extrusion coating, curtain coating, slide coating, dipping, doctor blade coating or a combination thereof.

The above-mentioned substrate includes a glass substrate, a polymer substrate, a metal substrate or a transparent conducting oxide (TCO) layer. The polymer substrate is, for example, polyimide (PI), polyethylene terephthalate) (PET), poly carbonate (PC) or poly(methyl methacrylate) (PMMA), and the transparent conducting oxide (TCO) layer is, for example, aluminum zinc oxide (ZnO:Al), indium tin oxide (In₂O₃:Sn), fluorine-doped tin oxide (SnO₂:F) or a combination thereof.

Additionally, the above Group IB, Group IIIA and bismuth compounds can be repeatedly deposited on the substrate to increase the thickness of the precursor compounds, and then heated in an atmosphere. Alternatively, after the heating process, the depositing step and heating step are repeated to control the thickness and characteristics of the bismuth-doped IB-IIIA-VIA compounds. In addition, when the depositing step is repeated, composition of the precursor compounds can be adjusted.

Then, the bismuth-doped IB-IIIA-VIA compounds are synthesized on the substrate via heating the substrate in the atmosphere. The above atmosphere includes the vacuum and non-vacuum, and the gas includes oxygen (O₂), nitrogen (N₂), hydrogen (H₂), argon (Ar) or a combination thereof. The temperature of the above heating process is about 350° C.-650° C., preferably about 400° C.-600° C. and the time of the heating process is about 0.1 hr to 8 hr, preferably about 0.3 hr to 6 hr, and most preferably 0.5 hr to 4 hr. The bismuth-doped IB-IIIA-VIA compounds of the invention can be obtained after the heating process, which can be applied to the photovoltaic devices. To facilitate the reaction, the above gas also includes the Group VIA gas, such as hydrogen selenide (H₂Se), hydrogen sulfide (H₂S), selenium (Se) steam, sulfur (S) steam, tellurium (Te) steam or a combination thereof.

Compared to traditional methods for manufacturing the IB-IIIA-VIA compounds, the IB-IIIA-VIA compounds having the great grain and high crystallinity are obtained by means of doping bismuth in the method of the invention. Additionally, the method of the invention is characterized in that the electrical characteristics of the IB-IIIA-VIA compounds is increased by doping the bismuth element, so as to enhance the photovoltaic characteristics of the photovoltaic devices.

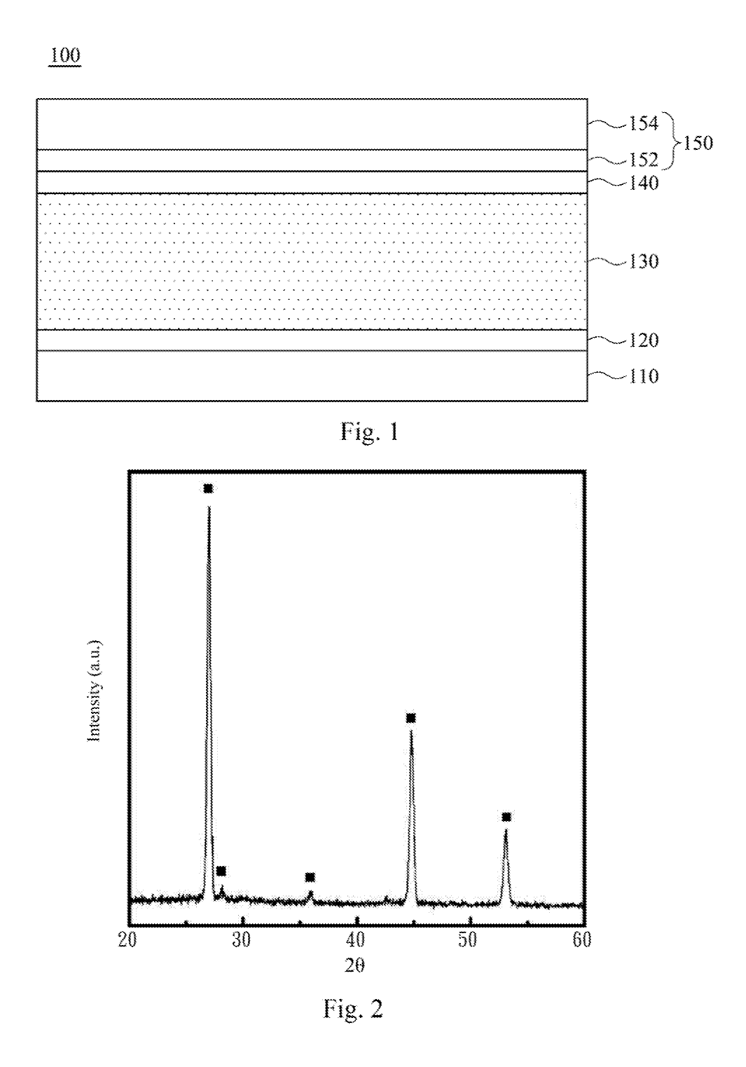

FIG. 1 is a schematic diagram of a solar cell 100 according to an embodiment of the invention. The solar cell 100 includes a substrate 110, a contact layer 120, a light absorber layer 130, a buffer layer 140 and a transparent conducting stack structure 150. However, those of skills in the art should know that the solar cell structure is not limited to the structure shown in FIG. 1.

The substrate 110 includes the glass substrate, the polymer substrate, the metal substrate or the transparent conducting oxide layer. The contact layer 120 may be a metal layer including molybdenum, so as to be used as a rear electrode of the solar cell. The metal layer including molybdenum can be formed on the substrate 110 by means of sputtering.

The light absorber layer 130 includes the bismuth-doped IB-IIIA-VIA compounds manufactured by the above embodiments. For example, a mixture of the precursors of the bismuth, Group IB and Group IIIA can be prepared firstly, and then a precursor bulk material or a thin film is formed on the substrate 110 by means of non-vacuum slurry coating, sputtering, evaporation or a combination thereof. Then, the bismuth-doped IB-IIIA-VIA compounds are synthesized via heating the precursor bulk material or thin film in the atmosphere including the Group VIA element.

The material of the buffer layer 140 is, for example, a CdS.ZnS, or In₂S₃ thin film. The window layer 150 may include a transparent window layer 152 and a transparent conducting layer 154. The material of the transparent window layer 152 is, for example, un-doped zinc oxide (i-ZnO). The material of the transparent conducting layer 154 is, for example, indium tin oxide (ITO), aluminum zinc oxide (AZO) or a combination thereof. In the other kind of processes, the transparent window layer 152 can be omitted. The light absorber layer 130 including the bismuth-doped IB-IIIA-VIA compounds formed by the embodiment of the invention can contribute to enhance the photovoltaic characteristics of the solar cell 100, as referred to the following embodiments.

### EMBODIMENTS

### Embodiment 1

The Cu(NO₃)₂, Ga(NO₃)₃ and In(NO₃)₃ are dissolved in ethyl alcohol according to the composition of Cu(In, Ga)Se₂ to form a solution, with the Bi(NO₃)₃ being added as a modifier, wherein the mole ratio of Bi(NO₃)₃ to Cu(In, Ga)Se₂ is 1:100; after a uniform mixture, a precursor solution is formed and further coated on the glass substrate by means of spin coating, wherein a thin film sample 1 can be obtained by firstly heating the precursor solution for 30 min at 250° C. to exclude organics, then heating the precursor film in mixed gases of nitrogen and hydrogen with high purity for 0.5 hr at 550° C. and then introducing the selenium steam thereto.

The result of an X-ray diffraction pattern analysis is shown as FIG. 2, wherein it can be seen that the thin film sample 1 has main diffraction peaks including (112), (211), (220), (204), (312) and (116), etc., which is consistent with the No. 35-1101 pattern on the ICDD card, so that it is confirmed the thin film sample 1 has a single phase structure of chalcopyrite phase crystal.

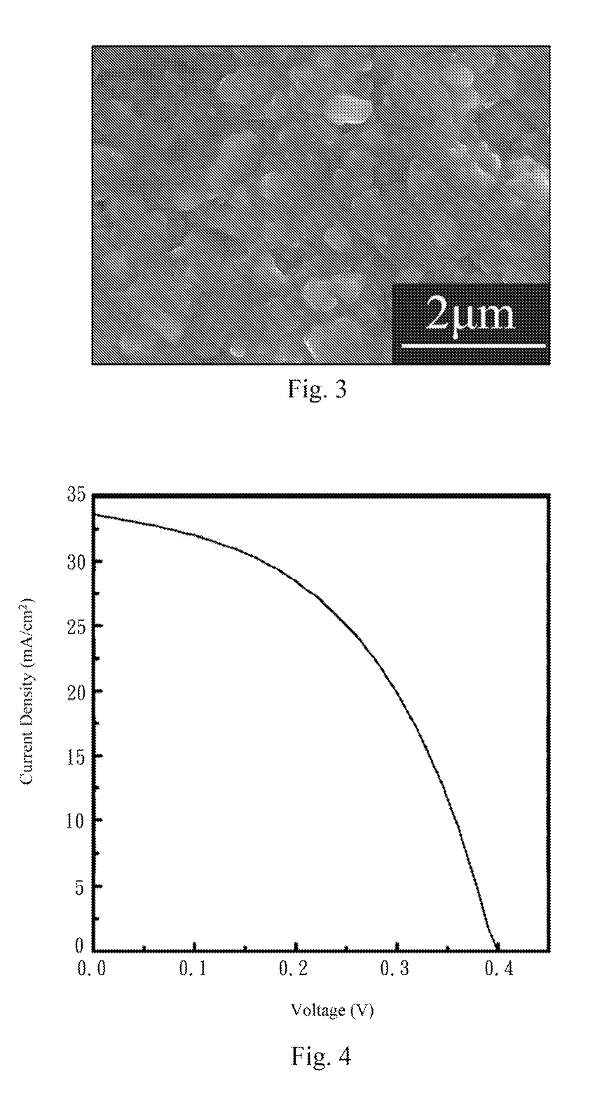

Additionally, the compound sample 1 is analyzed with a scanning electron microscope (SEM) and an atomic force microscope (AFM). The experimental result shows that the surface shape of the compound sample 1 is compacted and distributed uniformly, and the average grain size is about 0.7 μm, as shown in FIG. 3; and the surface roughness is about 60 nm. The carrier concentration of the compound sample 1 is 8.6×10¹⁶ cm⁻³, as analyzed by the Hall measurement.

Moreover, the compound sample 1 is further analyzed with an energy dispersive spectrometer (EDS) and an X-ray photoelectron spectroscopy (XPS), wherein characteristic peaks of Bi 4f_{7/2} and Bi 4f_{5/2} are found at 156.9 eV and 162.2 eV in the XPS analysis result. The experimental result proves that the bismuth element is really existed in the bismuth-doped thin film sample 1.

A copper indium gallium selenide thin film solar cell 1 is manufactured from a structure of glass/Mo/thin film sample 1/CdS/i-ZnO/ITO; and moreover, the copper indium gallium selenide thin film solar cell 1 is analyzed with a standard solar simulator, with the experimental result shown in FIG. 4, wherein it is shown that V_{oc} (open-circuit voltage) of the copper indium gallium selenide thin film solar cell 1 is 0.4 V, and J_{sc} (short-circuit current density) thereof is 33.7 mA/cm², and the photovoltaic conversion efficiency is 6.3%.

### Comparative Embodiment 1

The Cu(NO₃)₂, Ga(NO₃)₃ and In(NO₃)₃ are dissolved in ethyl alcohol according to the composition of Cu(In, Ga)Se₂ to form the solution, and after a uniform mixture, the precursor solution is formed to be coated on the glass substrate by means of spin coating, wherein a thin film sample 2 can be obtained by firstly heating the precursor solution for 30 min at 250° C. to exclude the organics, then heating the precursor solution in the mixed gases of nitrogen and hydrogen with high purity for 0.5 hr at 550° C. and then introducing the selenium steam thereto.

Through the X-ray diffraction pattern analysis, it is shown that the thin film sample 2 has the main diffraction peaks including (112 (211), (220), (204), (312) and (116), etc., which is consistent with the No. 35-1101 pattern on the ICDD card, so that it is confirmed that the thin film sample 2 has the single phase structure of chalcopyrite phase crystal.

The compound sample 2 is analyzed with the scanning electron microscope and the atomic force microscope with the result shown in FIG. 5, wherein the grain size is 0.3-0.6 μm and the average grain size is about 0.45 μm; and the surface roughness is about 150 nm. The carrier concentration of the compound sample 2 is 3.5×10¹⁶ cm⁻³, as analyzed with the Hall measurement. Compared to the sample 1 containing bismuth, it is found that the bismuth-free sample 2 has a smaller grain size and the thin film surface is rougher; and the carrier concentration is also lower. Moreover, no signal representing bismuth is found by analyzing with the EDS and the XPS. Therefore, it can be seen that adding bismuth can really increase the grain size and compactness of the chalcopyrite phase and enhance the carrier concentration of the chalcopyrite phase.

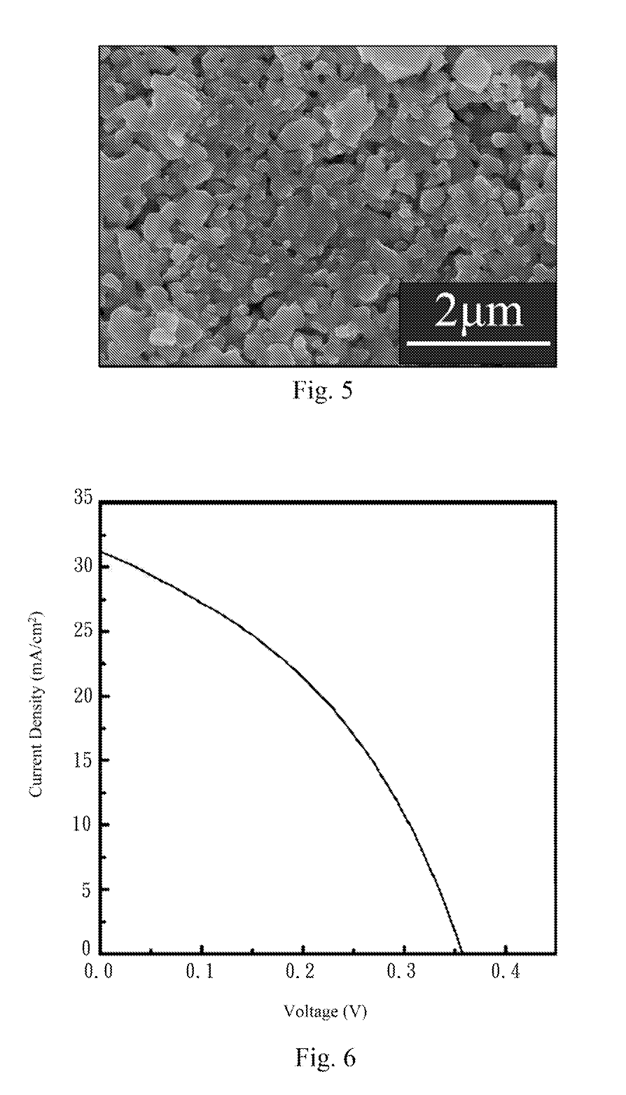

A copper indium gallium selenide thin film solar cell 2 is manufactured from the structure of glass/Mo/thin film sample 2/CdS/i-ZnO/ITO; and moreover, the copper indium gallium selenide thin film solar cell 2 is analyzed with the standard solar simulator, with the experimental result shown in FIG. 6, wherein V_{oc} (open-circuit voltage) is 0.36 V, and J_{sc} (short-circuit current density) is 31.2 mA/cm², and it is shown that the conversion efficiency of the copper indium gallium selenide thin film solar cell 2 is 4.4%. Therefore, it can be seen that the conversion efficiency (6.3%) of the bismuth-doped copper indium gallium selenide thin film solar cell 1 (Embodiment 1) is really greater than the conversion efficiency of the copper indium gallium selenide thin film solar cell 2 without doping bismuth (Comparative Embodiment 1).

### Embodiment 2

The CuCl₂ and InCl₃ are dissolved in methyl alcohol according to the composition of Cu_{0.8}In_{1.2}Se_{2.2} to form a solution, and the solution is coated on the glass substrate sputtered with Mo by means of spin coating, and then the BiCl₃ solution is prepared as the modifier and is coated on the coated precursor thin film of the above solution by means of spin coating, wherein the mole ratio of BiCl₃ to Cu_{0.8}In_{1.2}Se_{2.2} is 1.50; and finally, a thin film sample 3 is obtained by calcining in a hydrogen (H₂) atmosphere containing the selenium steam for 0.1 hr at a temperature of 600° C.

The result of the X-ray diffraction pattern analysis shows that the thin film sample 3 has main diffraction peaks including (111), (204), (220), (116), (312), so that it is confirmed that the thin film sample 3 has the single phase structure of chalcopyrite phase crystal.

In addition, the compound sample 3 is analyzed with the scanning electron microscope and the atomic force microscope, wherein the average grain size is about 3 μm and the surface roughness is 43 nm, and the carrier concentration of the thin film sample 3 is 1.2×10¹⁸ cm⁻³ as analyzed with the Hall measurement. Moreover, it can be seen from table 1 and table 2, the grain size of the bismuth-doped thin film sample 1 (Embodiment 1) or the bismuth-doped thin film sample 3 (Embodiment 2) is really greater than that of the compound sample 2 without doping bismuth (Comparative Embodiment 1), and the roughness of the thin film sample 1 or 3 is really lower than that of the compound sample 2. The carrier concentration can thus really be enhanced effectively.

TABLE 1

| | average size |
|---|---|
| Embodiment 1 | 0.7 μm |
| Comparative Embodiment 1 | 0.45 μm |
| Embodiment 2 | 3 μm |

TABLE 2

| | average roughness |
|---|---|
| Embodiment 1 | 60 nm |
| Comparative Embodiment 1 | 150 nm |
| Embodiment 2 | 43 nm |

### Embodiment 3

The CuO, Ga₂O₃ and Se powder are uniformly mixed according to the composition of CuGa_{0.8}Seₜ₇ by means of ball milling, and the (CH₃CO₂)₃Bi is added as the modifier, wherein the mole ratio of (CH₃CO₂)₃Bi to CuGa_{0.8}Se_{1.7} is 1:300. The resulted powder is dried and prepared to be slurry, and the slurry is coated on the glass substrate by means of the doctor-blading method; and then a thin film sample 4 can be obtained by performing a reaction in the hydrogen (H₂) atmosphere containing the selenium steam for 20 hr at the temperature of 180° C.

The result of X-ray diffraction pattern analysis shows that the thin film sample 4 has the main diffraction peaks including (112), (220), (204), (312) and (116)/(303), etc., wherein (116) and (303) are the diffraction peaks at the same position, so that it is confirmed that the thin film sample 4 has the single phase structure of chalcopyrite phase crystal.

### Embodiment 4

The Ag and Al are deposited on the TCO glass substrate having the deposited bismuth according to the composition of AgAlS₂ by means of sputtering, wherein the mole ratio of Bi to AgAlS₂ is 1:60. A thin film sample 5 is then obtained by performing the reaction in the H₂S atmosphere for 10 hr at 300° C.

The result of X-ray diffraction pattern analysis shows that the thin film sample 5 has the main diffraction peaks including (112), (103), (211), (220) and (204), etc. so that it is confirmed that the thin film sample 5 has the single phase structure of chalcopyrite phase crystal.

### Embodiment 5

The Ag(NO₃)₂ and In(NO₃)₃ are mixed to form an electroplating solution according to the composition of AgIn_{0.8}Te_{1.7}, and the Bi(NO₃)₃ is added as the modifier, wherein the mole ratio of Bi(NO₃)₃ to AgIn_{0.8}Te_{1.7} is 1:50. The electroplating solution is deposited on the glass substrate by means of an electroplating method, and then a thin film sample 6 is obtained by performing the reaction in the tellurium (Te) steam at 300° C.

The result of X-ray diffraction pattern analysis shows that the thin film sample 6 has the main diffraction peaks including (112), (220), (204), (312) and (303)/(116), etc., wherein (303) and (116) are the diffraction peaks at the same position, so that it is confirmed that the thin film sample 6 has the single phase structure of chalcopyrite phase crystal.

### Embodiment 6

The CuCl₂, AlCl₃ and SeCl₄ are dissolved in deionized water according to the composition of CuAlSe₂ component to form a solution, and the Bi(CH₃COO)₃ is added as the modifier, wherein the mole ratio of Bi(CH₃COO)₃ to CuAlSe₂ is 1:1000, and a precursor solution is formed after a uniform mixing. The precursor solution is then coated on the polymer substrate by means of spraying, and finally a thin film sample 7 is obtained by heating in a vacuum environment for 10 hr at 406° C.

The result of X-ray diffraction pattern analysis shows that the thin film sample 7 has the main diffraction peaks including (112), (220), (204), (312) and (116), etc., so that it is confirmed that the thin film sample 7 has the single phase structure of chalcopyrite phase crystal.

### Embodiments 7-10

The Cu(NO₃)₂, Ga(NO₃)₃ and In(NO₃)₃ are dissolved in the ethyl alcohol according to the composition of Cu(In, Ga)Se₂ to form a solution, and the Bi(NO₃)₃ is added as the modifier, wherein the mole ratio of Bi(NO₃)₃ to Cu(In, Ga)Se₂ is 1.5:100; and a precursor solution is formed after a uniform mixing. The precursor solution is then coated on the glass substrate by means of spin coating, and finally a thin film sample 8 (Embodiment 7), a thin film sample 9 (Embodiment 8), a thin film sample 10 (Embodiment 9) and a thin film sample 1 (Embodiment 10) are obtained by firstly heating for 30 min at 250° C. to exclude the organics and then elevating the temperature to 350° C., 400° C. 450° C. and 500° C. (without keeping a constant temperature) in the mixed gases of nitrogen and hydrogen with high purity including introduced selenium steam.

Through the X-ray diffraction pattern analysis, it is shown that in the thin film samples 8, 9 the chalcopyrite phase and Cu₂₋ₓSe phase are coexisted; and the thin film samples 10, 11 have the main diffraction peaks including (112), (211), (220), (204), (312) and (116), etc., which is consistent with the No. 35-1101 pattern on the ICDD card, so that it is confirmed that the thin film samples have the single phase structure of chalcopyrite phase crystal.

### Comparative Embodiments 2-5

The Cu(NO₃)₂, Ga(NO₃)₃ and In(NO₃)₃ are dissolved in ethyl alcohol according to the composition of Cu(In, Ga)Se₂ to form a solution, and a precursor solution is formed after a uniform mixing. The precursor solution is then coated on the glass substrate by means of spin coating, and finally a thin film sample 12 (Comparative Embodiment 2), a thin film sample 13 (Comparative Embodiment 3), a thin film sample 14 (Comparative Embodiment 4) and a thin film sample 15 (Comparative Embodiment 5) are obtained by firstly heating for 30 min at 250° C. to exclude the organics and then elevating the temperature to 350° C., 400° C., 450° C. and 500° C. (without keeping a constant temperature) in mixed gases of nitrogen and hydrogen with high purity including introduced selenium steam.

Through the X-ray diffraction pattern analysis, it is shown that the thin film samples 12, 13 belongs to the Cu₂₋ₓSe phase; in the thin film sample 14 the chalcopyrite phase and Cu₂₋ₓSe phase are coexisted; and the thin film sample 15 has the main diffraction peaks including (112), (211), (220), (204), (312) and (116), etc., which is consistent with the No. 35-1101 pattern on the ICDD card, so that it is confirmed that the thin film sample has the single phase structure of chalcopyrite phase crystal.

Therefore, single phase formation temperature (450° C.) of chalcopyrite phase of the bismuth-doped thin film sample 10 (Embodiment 9) is really lower than the single phase formation temperature (500° C.) of chalcopyrite phase of the thin film sample 15 without doping bismuth (Comparative Embodiment 5).

### Embodiment 11

The CuGa alloy and In are deposited on the substrate according to the composition of Cu(In, Ga)Se₂ by means of sputtering, and then Bi is deposited as the modifier by sputtering, such that the depositions are stacked as a precursor film. In the mixed gases of nitrogen and hydrogen with high purity including introduced selenium steam, the precursor film is heated at 550° C. for 0.5 hr so as to obtain the thin film sample 16.

Through the X-ray diffraction pattern analysis, it is shown that the thin film sample 16 has the main diffraction peaks including (112), (211), (220), (204), (312) and (116), etc., which is consistent with the No. 35-1101 pattern on the ICDD card, so that it is confirmed that the thin film sample 16 has the single phase structure of chalcopyrite phase crystal. In addition, the thin film sample 16 is analyzed with the SEM, and the result of analysis exhibits the thin film sample 16 has a uniform and dense surface wherein the average grain size is about 2-2.5 μm; and the carrier concentration of the thin film sample 16 is 1.2×10¹⁷ cm⁻³ as analyzed with the Hall measurement. Moreover, the thin film sample 16 is further analyzed with the EDS. The experimental result proves that the bismuth element is really existed in the thin film sample 16.

A copper indium gallium selenide thin film solar cell 16 is manufactured from the structure of glass/Mo/thin film sample 16/CdS/i-ZnO/ITO. And the copper indium gallium selenide thin film solar cell 16 is analyzed with the standard solar simulator. It is shown that the conversion efficiency of the copper indium gallium selenide thin film solar cell 16 is 8.55%, Comparative Embodiment 6

The CuGa alloy and In are deposited on the substrate according to the composition of Cu(In, Ga)Se₂ by means of sputtering, such that the depositions are stacked as a precursor film. In the mixed gases of nitrogen and hydrogen with high purity including introduced selenium steam, the precursor film is heated at 550° C. for 0.5 hr so as to obtain the thin film sample 17.

Through the X-ray diffraction pattern analysis, it is shown that the thin film sample 17 has the main diffraction peaks including (112), (211), (220), (204), (312) and (116), etc., which is consistent with the No. 35-1101 pattern on the ICDD card, so that it is confirmed that the thin film sample has the single phase structure of chalcopyrite phase crystal.

The carrier concentration of the thin film sample 17 is 8.6×10¹⁶ cm⁻³ as analyzed with the Hall measurement. Compared with the analysis result of the thin film sample 16, the Bi-free thin film sample 17 has the lower carrier concentration. Moreover, the experimental result of the EDS analysis proves that no bismuth element exists in the thin film sample 17. As a result, the addition of Bi in the depositions does raise the carrier concentration of the thin film.

A copper indium gallium selenide thin film solar cell 17 is manufactured from the structure of glass/Mo/thin film sample 17/CdS/i-ZnO/ITO. And the copper indium gallium selenide thin film solar cell 17 is analyzed with the standard solar simulator. It is shown that the conversion efficiency of the copper indium gallium selenide thin film solar cell 17 is 7.57%. As such, it can be seen that the conversion efficiency (8.55%) of the bismuth-doped copper indium gallium selenide thin film solar cell 16 (Embodiment 11) is really greater than the conversion efficiency of the copper indium gallium selenide thin film solar cell 17 free of bismuth (Comparative Embodiment 6).

Therefore, according to an embodiment of the invention, the average grain size of the bismuth-doped IB-IIIA-VIA compounds of the light absorber layers is greater than or equal to 0.6 μm, preferably greater than or equal to 0.8 μm, and most preferably the greater than or equal to 1.0 μm.

It can be seen from the above embodiments that, by doping the bismuth into original materials (IB-IIIA-VIA compounds) of the light absorber layer according to the process of the embodiments of the invention, the carrier concentration of the light absorber layers is really enhanced significantly, the crystallinity is enhanced, the grain size is increased and the roughness is reduced, so that the conversion efficiency of the solar cells can be effectively enhanced.

What is claimed is:

1. A method for manufacturing light absorber layers of bismuth-doped IB-IIIA-VIA compounds, comprising:
(A) depositing a precursor thin film containing Group IB, Group IIIA and bismuth compounds; and
(B) heating the precursor thin film in an atmosphere containing Group VIA species.

2. The method of claim 1, wherein, the Group IB element is selected from a group consisting of copper, silver, gold and a combination thereof.

3. The method of claim 1, wherein, the Group IIIA element is selected from a group consisting of boron, aluminum, gallium, indium, thallium and a combination thereof.

4. The method of claim 1, wherein, the Group VIA element is selected from a group consisting of oxygen, sulfur, selenium, tellurium, polonium and a combination thereof.

5. The method of claim 1, wherein, a mole ratio of the IB-IIIA-VIA to the bismuth is from 10:1 to 2000:1.

6. The method of claim 1, wherein, the step (A) further comprises: adding Group IA and/or Group VIA compounds into the precursor thin film.

7. The method of claim 1, wherein, the step (A) further comprises: thermally treating the precursor thin film before the step (B).

8. The method of claim 7, wherein, the precursor thin film is thermally treated at 50° C.-650° C.

9. The method of claim 1, wherein, the depositing method of the step (A) comprises a vacuum film-coating process, a non-vacuum film-coating process or a combination thereof.

10. The method of claim 1, wherein, the depositing method of the step (A) comprises coating, sputtering, evaporation or a combination thereof.

11. The method of claim 10, wherein the coating method comprises spin coating, slot coating, extrusion coating, curtain coating, slide coating, dipping, doctor blade coating or a combination thereof.

12. The method of claim 1, wherein the atmosphere of the step (B) comprises vacuum or non-vacuum.

13. The method of claim 12, wherein the atmosphere comprises oxygen (O₂), nitrogen (N₂), hydrogen (H₂), argon (Ar), hydrogen selenide (H₂Se), hydrogen sulfide (H₂S), selenium (Se) steam, sulfur (S) steam, tellurium (Te) steam or a combination thereof.

14. A solar cell employing light absorber layers of bismuth-doped IB-IIIA-VIA compounds according to claim 1.

15. The solar cell of claim 14, wherein an average grain size of the bismuth-doped IB-IIIA-VIA compounds of the light absorber layers is greater than or equal to 0.6 μm.
